(19) United States
(12) Patent Application Publication
(10) Pub. No.: US 2025/0037928 A1
(43) Pub. Date: Jan. 30, 2025

(54) MOLD TRANSFORMER

(71) Applicant: LS ELECTRIC CO., LTD., Anyang-si, Gyeonggi-do (KR)

(72) Inventor: Yoon Sun LEE, Anyang-si, Gyeonggi-do (KR)

(21) Appl. No.: 18/841,564

(22) PCT Filed: Feb. 1, 2023
(86) PCT No.: PCT/KR2023/001430

§ 371 Date: Aug. 26, 2024

(30) Foreign Application Priority Data
Mar. 29, 2022 (KR) 10-2022-0038505

(51) Int. Cl. H01F 27/28; H01F 27/02; H01F 27/04; H01F 27/32; H01F 30/06

(52) U.S. Cl. CPC H01F 27/2885; H01F 27/022; H01F 27/04; H01F 27/2828; H01F 27/327; H01F 30/06

(57) ABSTRACT

The present disclosure discloses a mold transformer which is capable of further relaxing the ambient electric field distribution thereof, the mold transformer comprising: a winding part; a shield member formed in a columnar shape having a hollow space formed therein and formed of an electrically conductive material, wherein a part of a lead wire of the winding part is inserted through and coupled to the hollow space; and a mold part disposed to surround the winding part and the shield member and formed of an electrical insulation material.

### CROSS-REFERENCE TO RELATED APPLICATIONS

This application is the National Stage filing under 35 U.S.C. 371 of International Application No. PCT/KR2023/001430, filed on Feb. 1, 2023, which claims the benefit of earlier filing date and right of priority to Korean Application No. 10-2022-0038505, filed on Mar. 29, 2022, the contents of which are all hereby incorporated by reference herein in their entirety.

### FIELD

The present disclosure relates to a mold transformer, and more specifically to a mold transformer in which the ambient electric field distribution can be more relaxed.

### BACKGROUND

Transformers are devices that change current or voltage by using electromagnetic induction. Transformers can be classified into immersed transformers, dry-type transformers and mold transformers depending on their insulation method.

Among these, mold transformers refer to transformers that insulate the outside of the winding by wrapping the same with a solid insulator. The demand for mold transformers is increasing due to the emergence of insulators with excellent heat resistance and flame retardancy, such as epoxy, without using oil, which is highly likely to cause environmental pollution.

However, on the surface of the insulating material surrounding the high-voltage winding part of the mold transformer, the electric field may be concentrated in a specific area, and a leakage current may be generated. This reduces the insulation performance and efficiency of the transformer and may cause damage to components.

Therefore, the development of a mold transformer in which the electric field distribution on the surface of the insulating material can be more relaxed may be considered.

Korean Patent Application Laid-Open No. 10-2018-0018091 discloses an epoxy nanocomposite composition for outdoor electrical insulation materials. Specifically, an epoxy nanocomposite composition with improved insulation performance by adding nano silica to epoxy is disclosed.

However, in order for this composition to be used in a mold transformer, specific materials are essentially required, and thus, there are limits to the improvement of materials alone. Additionally, a fundamental solution to electric field distribution concentrated in a specific area is not disclosed.

Korean Registered Patent No. 10-1658349 discloses a mold transformer with reinforced strength and insulation performance. Specifically, a mold transformer formed by stacking various insulating reinforcing materials and having an increased thickness of epoxy resin is disclosed.

However, this type of mold transformer has a problem in that the manufacturing process thereof and overall volume increase, resulting in increases in materials and costs.

(Patent Document 1) Korean Patent Application Laid-Open No. 10-2018-0018091 (Feb. 21, 2018)

(Patent Document 2) Korean Registered Patent No. 10-1658349 (Sep. 12, 2016)

### SUMMARY

An object of the present disclosure is to provide a mold transformer in which the ambient electric field distribution can be more relaxed.

Another object of the present disclosure is to provide a mold transformer with improved transformer reliability.

Still another object of the present disclosure is to provide a mold transformer whose manufacturing process is simple and easy.

In order to achieve the above objects, the mold transformer according to an aspect of the present disclosure includes a winding part which is wound around an iron core, and has a lead wire that extends aways from the iron core; a shield member which is formed in a columnar shape having a hollow space formed therein, and is formed of an electrically conductive material, wherein a part of the lead wire is inserted through and coupled to the hollow space; and a mold part which is disposed to surround the winding part and the shield member, and is formed of an electrical insulation material.

In addition, the mold part may include a winding part mold which is disposed to cover and surround the winding part except for the lead wire; a shield part mold which is coupled to one side of the winding part mold, and is disposed to cover and surround the shield member and a portion of the lead wire that is located inside the shield member; and a bushing mold which is coupled to the winding part mold with the shield part mold interposed therebetween, and is disposed to cover and surround another portion of the lead wire that is located outside the shield member.

In addition, the winding part mold and the shield part mold may have a semiconducting layer coated on the surfaces thereof.

In addition, the shield member may include a small diameter part which is formed in a cylindrical shape; and a large diameter part which is formed by extending from both ends of the small diameter part, and extends while being curved toward an outer peripheral surface of the small diameter part.

In addition, the distance between one end of the shield member opposite to the iron core and the iron core may be formed to be longer than the distance between one end of the shield part mold opposite to the iron core and the iron core.

In addition, the large diameter part which is located at one end opposite to the iron core of the shield member may extend and curve toward one end opposite to the iron core of the small diameter part.

In addition, the large diameter part, which is located at one end opposite to the iron core of the shield member, may have the end thereof in contact with a side surface of the small diameter part.

In addition, the winding part may include a low-voltage winding part which is wound on a portion of the iron core; and a high-voltage winding part which is wound on another portion of the iron core, and is spaced apart from the low-voltage winding part.

In addition, the low-volage winding part may be respectively disposed on the upper and lower sides of the high-voltage winding part in the axial direction of the high-voltage winding part.

In addition, the shield part mold may be formed in a shape corresponding to the shield member.

In addition, the shield part mold may be extended with an axial cross-sectional area increasing toward a boundary with the winding part mold or a boundary with the bushing mold.

In addition, the bushing mold may include a plurality of protrusion parts which extend radially outwardly from the lead wire; and a recessed part which is formed to be recessed between two adjacent protrusion parts, wherein the protrusion part and the recessed part are arranged alternately along the axial direction.

In addition, the mold part may be made of an epoxy resin.

In addition, the shield member may include a ground part which is exposed to the outside of the mold part.

In addition, the shield member may be formed in a mesh structure. In addition, the shield member may be formed of an aluminum (Al) material.

Among the various effects of the present disclosure, the effects that can be obtained through the above-described solution are as follows.

First of all, the mold transformer includes a low-voltage winding part, a high-voltage winding part, a shield member and a mold part. In this case, the shield member is made of an electrically conductive material, and a portion of the high-voltage lead wire is penetrated and coupled to the internal hollow space. The mold part is formed of an electrically insulating material and is disposed to surround the high-voltage winding part and the shield member.

Accordingly, part of the electric field on the surface of the mold part may be concentrated inside the mold part by the shield member. Accordingly, the electric field distribution around the mold transformer can be more relaxed. As a result, the insulation performance of the mold part can be further improved.

Additionally, as insulation performance improves, leakage current can be further reduced. That is, the loss of current passing through the mold transformer can be further reduced.

Accordingly, the voltage transformation reliability of the mold transformer can be further improved. Furthermore, the reliability of power devices including molded transformers can also be improved.

In addition, the shield member is disposed such that the exterior thereof is surrounded by the mold part. For this purpose, the shield member is placed inside the mold for the mold transformer before mold injection. That is, in order to add a shield member to an existing mold transformer, only a simple process of attaching a high-voltage lead wire through the shield member before mold injection is required.

Accordingly, the shield member can be added without excessive modification of the existing structure of the molded transformer. Accordingly, the mold transformer is provided with a shield member, and can be manufactured in a simple and easy manner at the same time.

### BRIEF DESCRIPTION OF THE DRAWINGS

FIG. 1 is a perspective view illustrating a mold transformer according to an exemplary embodiment of the present disclosure.

FIG. 2 is an exploded perspective view illustrating the mold transformer of FIG. 1.

FIG. 3 is an exploded perspective view illustrating the iron core, winding part, insulating member, shield member and mold part that are provided in the mold transformer of FIG. 1.

FIG. 4 is a perspective view illustrating the shield member of FIG. 3.

FIG. 5 is a partial cross-sectional view illustrating the shield member of FIG. 4.

FIG. 6 is a perspective view illustrating the mold part of FIG. 3.

FIG. 7 is a side view illustrating the mold part of FIG. 3.

FIG. 8 is a partial cross-sectional view illustrating the shield member and mold part of FIG. 3.

### DETAILED DESCRIPTION

Hereinafter, the mold transformer 1 according to an exemplary embodiment of the present disclosure will be described in more detail with reference to the drawings.

In the following description, in order to clarify the characteristics of the present disclosure, the descriptions of some components may be omitted.

In the present specification, the same reference numerals are assigned to the same constitutions even in different exemplary embodiments, and the duplicate descriptions thereof will be omitted.

The attached drawings are only intended to facilitate understanding of the exemplary s disclosed in the present specification, and the technical idea disclosed in the present specification is not limited by the attached drawings.

Singular expressions include plural expressions unless the context clearly dictates otherwise.

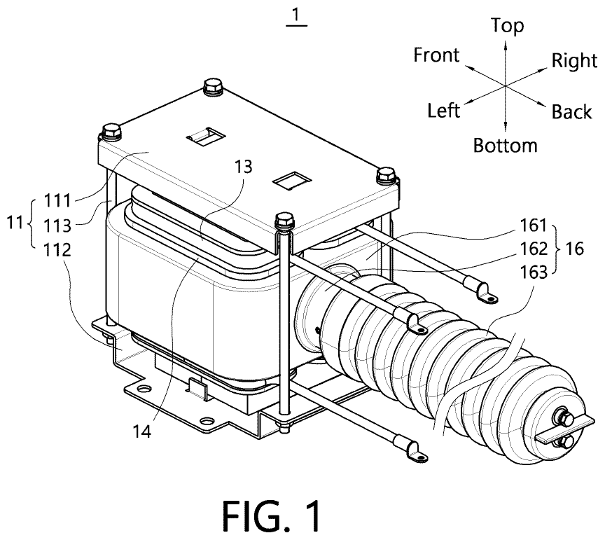

The terms “upper”, “lower”, “left”, “right”, “front side” and “back side” used in the following description will be understood with reference to the coordinate system illustrated in FIG. 1.

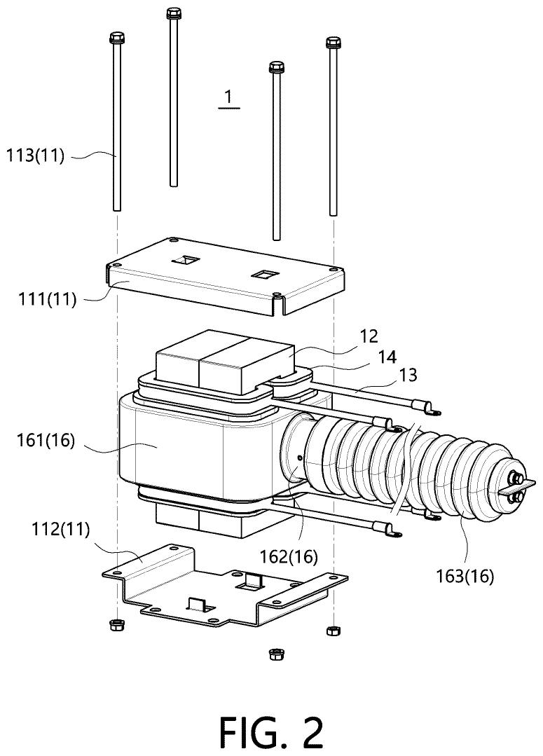

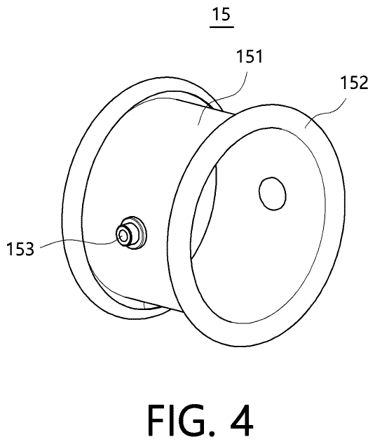

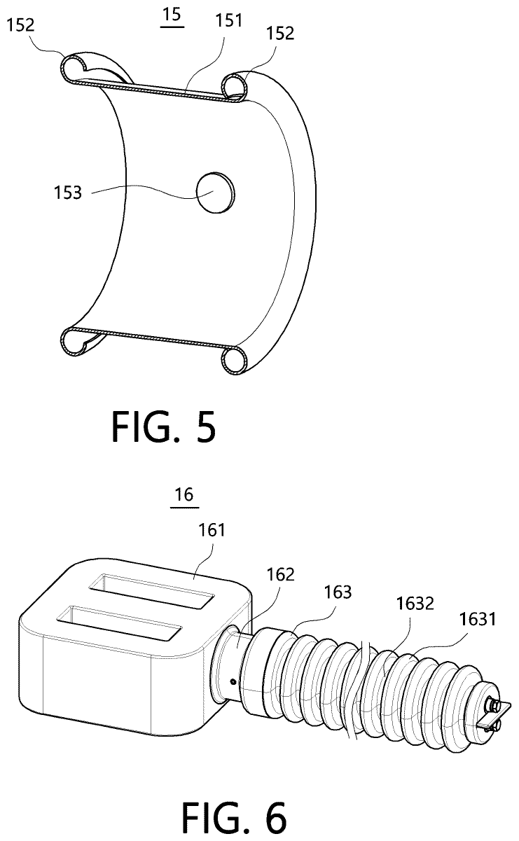

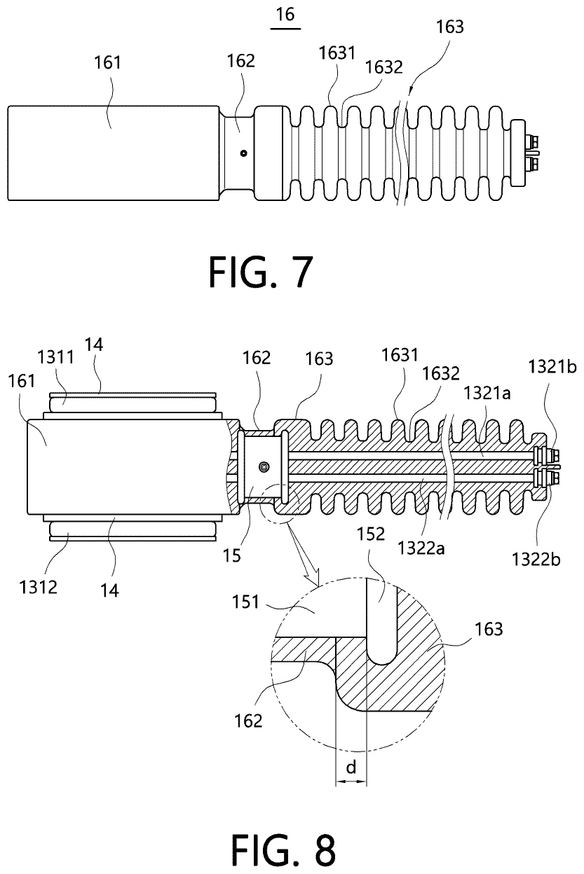

Hereinafter, the mold transformer 1 according to an exemplary embodiment of the present disclosure will be described with reference to FIGS. 1 to 8.

The mold transformer 1 uses electromagnetic induction to change the voltage of an input current and output the same. In this case, the mold transformer 1 insulates the outside of a high-voltage winding part 132 by wrapping the same with a solid insulator.

In the illustrated exemplary embodiment, the mold transformer 1 includes a support part 11, an iron core 12, a winding part 13, an insulating member 14, a shield member 15 and a mold part 16.

Hereinafter, the support part 11, the iron core 12, the winding part 13 and the insulating member 14 will be described with reference to FIGS. 1 to 3.

The support part 11 supports an iron core 12 and the winding part 13, which will be described below, in the axial direction. In the illustrated exemplary embodiment, the support part 11 supports the iron core 12 and the winding part 13 in the vertical direction.

The support part 11 separates the iron core 12 from the installation surface of the mold transformer 1. Through this, it is possible to prevent a direct contact between the iron core 12 and the installation surface, and accordingly, electric leakage accidents may also be prevented.

In an exemplary embodiment, the support part 11 may be formed of a high-strength material. For example, the support part 11 may be made of aluminum (Al).

In the illustrated exemplary embodiment, the support part 11 includes an upper frame 111, a lower frame 112 and a support 113.

The upper frame 111 and the lower frame 112 form the upper and lower exterior surfaces of the support part 11, respectively.

The upper frame 111 and the lower frame 112 are located above and below the iron core 12 and the winding part 13, respectively. In this case, the upper frame 111 and the lower frame 112 overlap the iron core 12 and the winding part 13 in the vertical direction. In an exemplary embodiment, the upper frame 111 and the lower frame 112 may have vertical cross-sectional areas that are larger than the vertical cross-sectional areas of the iron core 12 and the winding part 13.

The upper frame 111 and the lower frame 112 are spaced apart from each other. In addition, the upper frame 111 and the lower frame 112 are coupled with the iron core 12 and the winding part 13 interposed therebetween.

The upper frame 111 and the lower frame 112 may be formed in a plate shape extending in a direction intersecting the axial direction of the winding part 13. In the illustrated exemplary embodiment, the upper frame 111 and the lower frame 112 are each formed in a plate shape perpendicular to the vertical direction.

In an exemplary embodiment, the upper frame 111 and the lower frame 112 may be formed in shapes corresponding to the upper and lower surfaces of the iron core 12, respectively. In another exemplary embodiment, a protrusion to which the iron core 12 can be fixed may be formed on the upper surface of the lower frame 112.

The support 113 is disposed between the upper frame 111 and the lower frame 112.

The support 113 maintains a certain distance between the upper frame 111 and the lower frame 112. For this purpose, the support 113 is coupled to the upper frame 111 and the lower frame 112, respectively. In an exemplary embodiment, the support 113 may be fastened to the upper frame 111 and the lower frame 112 by bolting.

The support 113 is arranged to overlap the upper frame 111, the lower frame 112 and the winding part 13 in the axial direction. That is, the upper frame 111, the support 113 and the lower frame 112 are arranged side by side along the axial direction of the winding part 13. In the illustrated exemplary embodiment, the axial direction is up and down.

In an exemplary embodiment, the support 113 may be formed in a columnal shape extending in the axial direction of the winding part 13. In the illustrated exemplary embodiment, the support 113 extends in the vertical direction.

A plurality of supports 113 may be provided. In the illustrated exemplary embodiment, four supports 113 are provided.

The iron core 12 and the winding part 13 are disposed inside the support part 11.

The iron core 12 is formed of a magnetic material such as iron (Fe) and functions as a magnetic field of the mold transformer 1. Specifically, the iron core 12 functions as a magnetic field for the mutual induction phenomenon that occurs between a low-voltage winding part 131 and a high-voltage winding part 132 that are wound around the outer peripheral surface thereof.

The iron core 12 is located between the upper frame 111 and the lower frame 112 and is coupled to the bottom surface of the upper frame 111 and the upper surface of the lower frame 112, respectively.

The iron core 12 may be formed as an inner convex structure surrounded by the winding part 13 or an outer convex structure surrounding the winding part 13. In the illustrated exemplary embodiment, the iron core 12 is formed in a rectangular ring-shaped iron-type structure and is arranged to be surrounded by the winding part 13.

The iron core 12 may be formed by assembling a plurality of parts. In an exemplary embodiment, the iron core 12 may be formed by overlapping a plurality of steel plates in one direction. In the illustrated exemplary embodiment, the iron core 12 is formed by combining a plurality of parts in the vertical direction while penetrating the winding part 13.

The winding part 13 generates an induced electromotive force according to changes in the magnetic field.

The winding part 13 is formed of a wire made of an electrically conductive material. For example, the wire of the winding part 13 may be made of copper (Cu) or aluminum (Al).

The winding part 13 is located between the upper frame 111 and the lower frame 112. Additionally, the winding part 13 is arranged to overlap the upper frame 111 and the lower frame 112 in the axial direction thereof. In this case, the winding part 13 is spaced apart from the upper frame 111 and the lower frame 112.

The winding part 13 is wound around the outer peripheral surface of the iron core 12. That is, the winding part 13 is arranged to overlap the iron core 12 in the axial direction, and the iron core 12 is penetrated and coupled thereto. Accordingly, the magnetic field generated in the winding part 13 may be formed along the iron core 12.

In the illustrated exemplary embodiment, the winding part 13 is arranged to surround the iron core 12 on a radial outer side of the iron core 12. In an exemplary embodiment not illustrated, the winding part 13 may be located radially inside the iron core 12 and arranged to be surrounded by the iron core 12.

In addition, the winding part 13 is electrically connected to the primary and secondary devices that are subject to transformation by the mold transformer 1.

The winding part 13 includes a low-voltage winding part 131 and a high-voltage winding part 132.

The low-voltage winding part 131 is electrically connected to any one of the primary and secondary devices that are subject to transformation of the mold transformer 1.

The low-voltage winding part 131 is located at the upper and lower ends of the winding part 13, respectively. Additionally, the low-voltage winding part 131 is wound around a portion of the iron core 12.

In the illustrated exemplary embodiment, the low-voltage winding part 131 includes a first low-voltage winding 1311 and a second low-voltage winding 1312.

The first low-voltage winding 1311 and the second low-voltage winding 1312 are arranged side by side in the axial direction of the winding part 13. In this case, the first low-voltage winding 1311 and the second low-voltage winding 1312 are spaced apart from each other.

In the illustrated exemplary embodiment, the first low-voltage winding 1311 and the second low-voltage winding 1312 are arranged side by side in the vertical direction. In the above exemplary embodiment, the first low-voltage winding 1311 is located above the second low-voltage winding 1312.

The first low-voltage winding 1311 and the second low-voltage winding 1312 may each have a lead wire and a terminal formed at one end.

The high-voltage winding part 132 is electrically connected to the other one of the primary and secondary devices subject to transformation of the mold transformer 1 that is not connected to the low-voltage winding part 131.

The high-voltage winding part 132 is located at the center of the winding part 13. In addition, the high-voltage winding part 132 is wound around the iron core 12, but is wound on one part of the iron core where the low-voltage winding part 131 is wound and another part.

A first low-voltage winding 1311 and a second low-voltage winding 1312 disposed on the upper and lower sides of the high-voltage winding part 132, respectively, in the axial direction. In this case, the high-voltage winding part 132 is spaced apart from the first low-voltage winding 1311 and the second low-voltage winding 1312. The high-voltage winding part 132 and the low-voltage winding part 131 are physically separated by a mold part 16, which will be described below. The detailed description of this will be provided below.

In the illustrated exemplary embodiment, the high-voltage winding part 132 includes a first high-voltage winding 1321 and a second high-voltage winding 1322.

The first high-voltage winding 1321 and the second high-voltage winding 1322 are arranged in a direction crossing the axial direction of the winding part 13. In the illustrated exemplary embodiment, the first high-voltage winding 1321 and the second high-voltage winding 1322 are directly connected to each other and arranged side by side in the left and right directions. In the above exemplary embodiment, the first high voltage winding 1321 is located to the left of the second high voltage winding 1322.

A first high-voltage lead wire 1321a and a second high-voltage lead wire 1322a are formed at one end of the first high-voltage winding 1321 and the second high-voltage winding 1322, respectively.

The first high-voltage lead wire 1321a and the second high-voltage lead wire 1322a are arranged to be spaced apart from each other. In this case, the first high-voltage lead wire 1321a and the second high-voltage lead wire 1322a each extend in a direction away from the iron core 12.

A first high-voltage terminal 1321b and a second high-voltage terminal 1322b are coupled to one end of the first high-voltage lead wire 132 la and the second high-voltage lead wire 1322a, respectively.

The first high-voltage terminal 1321b and the second high-voltage terminal 1322b are conductively coupled to a primary or secondary device to be transformed by the mold transformer 1, respectively.

The low-voltage winding part 131 and the high-voltage winding part 132 are physically separated by a mold part 16, which will be described below. In this case, the low-voltage winding part 131 may be physically separated from the mold part 16 by an additional insulating member 14.

The insulating member 14 assists in electrical insulation between the low-voltage winding part 131 and other components.

The insulating member 14 is coupled to the low-voltage winding part 131 and is formed to surround at least a portion of the low-voltage winding part 131.

The insulating member 14 is disposed between the inner peripheral surface of the low-voltage winding part 131 and the iron core 12. Additionally, the insulating member 14 supports the low-voltage winding part 131 in the axial direction thereof and radially inside. In the illustrated exemplary embodiment, the insulating member 14 supports the low-voltage winding part 131 in the vertical direction and radially inwardly.

The insulating member 14 is located on the upper or lower side of the mold part 16, which will be described below. As described above, since the insulating member 14 supports the low-voltage winding part 131 in the vertical direction, the low-voltage winding part 131 may be physically separated from the mold part 16 by the insulating member 14.

A plurality of insulating members 14 may be provided. In this case, the number of insulating members 14 is formed to correspond to the number of low-voltage winding parts 131. In the illustrated exemplary embodiment, the insulating member 14 is coupled to the first low-voltage winding 1311 and the second low-voltage winding 1312, respectively.

In an exemplary embodiment, the insulating member 14 is formed in a shape corresponding to the winding structure of the low-voltage winding part 131. In the illustrated exemplary embodiment, the insulating member 14 is formed in a bobbin shape surrounding the top, bottom and inner peripheral surface of the low-voltage winding part 131.

The high-voltage winding part 132 provides electrical insulation between other components by the shield member 15 and the mold part 16, separately from the insulating member 14 coupled to the low-voltage winding part 131.

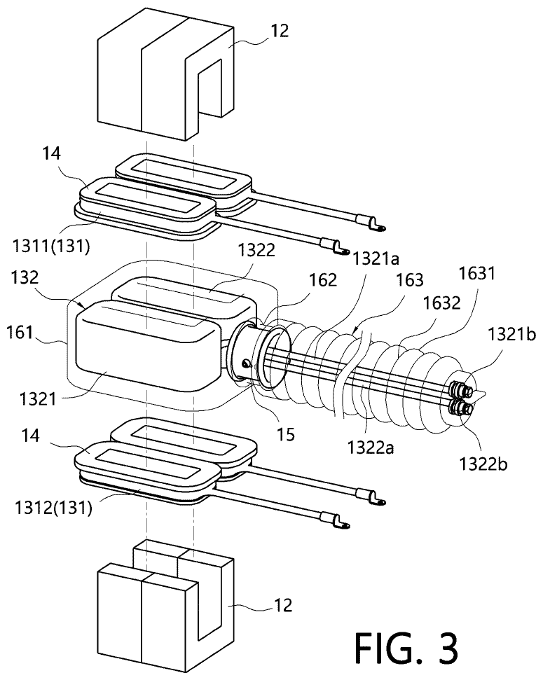

Hereinafter, the shield member 15 and the mold part 16 will be described in more detail with reference to FIGS. 3 to 8.

The shield member 15 further alleviates the electric field distribution surrounding the mold transformer 1.

The high-voltage winding part 132 penetrates and extends inside the shield member 15. That is, the shield member 15 is arranged to surround a portion of the high-voltage winding part 132 and attracts a portion of the electric field generated by the high-voltage winding towards the high-voltage winding part 132.

Specifically, the shield member 15 is arranged to surround the radial outside of the high-voltage lead wires 1321a, 1322a. That is, some of the high-voltage lead wires 1321a, 1322a are penetrated and coupled to the inside of the shield member 15. In an exemplary embodiment, the high-voltage lead wires 1321a, 1322a may be located in a straight line with the central axis of the shield member 15.

The shield member 15 is formed in a columnar shape with a hollow interior. Parts of the high-voltage lead wires 1321a, 1322a are coupled through the hollow.

In an exemplary embodiment, the shield member 15 may be formed in a mesh structure. This is to minimize air bubbles by passing through and absorbing the mold part 16 through a mesh network during the injection process of the mold part 16, which will be described below.

The shield member 15 is formed of an electrically conductive material. In an exemplary embodiment, the shield member 15 may be made of aluminum (Al). Accordingly, the shield member 15 may attract a portion of the electric field generated by the high-voltage winding part 132 back toward the high-voltage winding part 132.

In the illustrated exemplary embodiment, the shield member 15 includes a small diameter part 151, a large diameter part 152 and a ground part 153.

The small diameter part 151 forms the exterior of the shield member 15.

The small diameter part 151 is formed in a cylindrical shape extending in one direction. The one direction is the same as the extension direction of the high voltage lead wires 1321a, 1322a. In the illustrated exemplary embodiment, the small diameter part 151 extends in the front-to-back direction.

The small diameter part 151 is provided with a hollow interior. Parts of the high-voltage lead wires 1321a, 1322a are penetrated into the hollow.

Large diameter parts 152 are formed at both ends of the small diameter part 151, respectively.

The large diameter part 152 is formed to extend from both ends of the small diameter part 151. In the illustrated exemplary embodiment, the large diameter part 152 is formed at the front and rear ends of the small diameter part 151.

The large diameter part 152 is curved and extends toward the outer peripheral surface of the small diameter part 151. In an exemplary embodiment, the end of the large diameter part 152 may contact a side surface of the small diameter part 151.

In summary, the large diameter part 152 is curved and extends from both ends of the small diameter part 151 toward the outer peripheral surface of the small diameter part 151. Accordingly, the large diameter part 152 has an axial cross-sectional area larger than that of the small diameter part 151. In an exemplary embodiment, the large diameter part 152 may have a maximum radius that is 3 mm larger than the radius of the small diameter part 151.

A plurality of large diameter parts 152 may be provided at both ends of the small diameter part 151. In an exemplary embodiment, the plurality of large diameter parts 152 may be formed in shapes that correspond to each other. In another exemplary embodiment, the plurality of large diameter parts 152 may be formed in different shapes. In the illustrated exemplary embodiment, the large diameter part 152 on the front side is formed such that the end thereof does not contact the side surface of the small diameter part 151, and the large diameter part 152 on the rear side is formed so that the end thereof is in contact with the side surface of the small diameter part 151.

The ground part 153 is formed on the outer peripheral surface of the small diameter part 151.

The ground part 153 alleviates the external electric field of the shield member 15.

The ground part 153 may be electrically connected to the ground by a ground wire.

The ground part 153 is formed to protrude radially outward from the outer peripheral surface of the small diameter part 151. Additionally, the ground part 153 is exposed to the outside of the mold part 16, which will be described below.

The exteriors of the shield member 15 and the high-voltage winding part 132 are surrounded by the mold part 16.

Hereinafter, the mold part 16 will be described with reference to FIGS. 6 to 8.

The mold part 16 surrounds the outside of the high-voltage winding part 132 and insulates the surroundings of the high-voltage winding part 132.

The mold part 16 is formed of an electrically insulating material. In an exemplary embodiment, the mold part 16 may be formed of an epoxy material with excellent electrical insulation performance.

The mold part 16 is located between the upper frame 111 and the lower frame 112. Additionally, the mold part 16 is located between the first low-voltage winding 1311 and the second low-voltage winding 1312. In the illustrated exemplary embodiment, the mold part 16 is arranged to overlap the upper frame 111, the lower frame 112, the first low-voltage winding 1311 and the second low-voltage winding 1312 in the vertical direction.

The mold part 16 is arranged to surround the high-voltage winding part 132 and the shield member 15, and covers the high-voltage winding part 132 and the shield member 15. Accordingly, the mold part 16 may be formed integrally with the high-voltage winding part 132 and the shield member 15.

Since the mold part 16 is arranged to surround the periphery of the high-voltage winding part 132, a high-voltage electric field may be generated on the surface thereof. The high-voltage electric field may be alleviated by the shield member 15.

A shield member 15 is located between the outer peripheral surface of the mold part 16 and the high-voltage lead wires 1321a, 1322a. Accordingly, the electric field generated by the high-voltage lead wires 1321a, 1322a may be concentrated inside the mold part 16 by the shield member 15. Accordingly, the electric field distribution surrounding the mold transformer 1 may be more relaxed. As a result, the insulation performance of the mold part 16 may be further improved by the shield member 15.

Additionally, as insulation performance improves, leakage current may be further reduced. That is, the loss of current passing through the mold transformer 1 may be further reduced. Accordingly, the voltage transformation reliability of the mold transformer 1 may be further improved. Furthermore, the reliability of power devices including the molded transformer 1 may also be improved.

The mold part 16 may be formed in a shape corresponding to the high-voltage winding part 132 and the shield member 15.

In the illustrated exemplary embodiment, the mold part 16 includes a winding part mold 161, a shield part mold 162 and a bushing mold 163.

The winding part mold 161 electrically insulates a portion of the high-voltage winding part 132 excluding the high-voltage lead wires 1321a, 1322a.

The winding part mold 161 is disposed between the upper frame 111 and the lower frame 112. At the same time, the winding part mold 161 is disposed between the first low-voltage winding 1311 and the second voltage winding. In the illustrated exemplary embodiment, the upper frame 111, the first low-voltage winding 1311, the winding part mold 161, the second low-voltage winding 1312 and the lower frame 112 are sequentially arranged along the vertical direction.

The winding part mold 161 is arranged to cover and surround the high-voltage winding part 132 except for the high-voltage lead wires 1321a, 1322a. As described above, the low-voltage winding part 131 is located above and below the high-voltage winding part 132, respectively. Through this, it will be understood that the mold part 16 is located between the low-voltage winding part 131 and the high-voltage winding part 132.

Electrical conduction between the high-voltage winding part 132 and the low-voltage winding part 131 is insulated by the winding part mold 161, which is a solid insulating material rather than a fluid, and thus, the distance between the high-voltage winding part 132 and the low-voltage winding part 131 may be minimized.

The winding part mold 161 is formed in a shape corresponding to the winding structure of the high-voltage winding part 132. Accordingly, a through-hole is formed in the winding part 13 along the axial direction of the high-voltage winding part 132. The iron core 12 is inserted and coupled to the through-hole.

A semiconducting layer is coated on the surface of the winding part mold 161. This is to alleviate the bias of the electric field on the surface of the mold part 16. In an exemplary embodiment, the semiconducting layer may be formed of a polymer resin material mixed with carbon black. In another exemplary embodiment, the semiconducting layer may be formed of a polymer resin material mixed with acetylene black or furnace black.

The shield part mold 162 is located on one side of the winding part mold 161.

The shield part mold 162 insulates a portion of the high-voltage lead wires 1321a, 1322a located inside the shield member 15.

The shield part mold 162 is disposed between the upper frame 111 and the lower frame 112. In this case, a portion of the shield part mold 162 may overlap the support part 11 and the winding part 13 in the axial direction.

The shield part mold 162 is coupled to one side of the winding part mold 161. In the illustrated exemplary embodiment, the shield part mold 162 is coupled to the rear side of the winding part mold 161.

The shield part mold 162 is arranged to cover and surround the shield member 15 and a portion of the high-voltage lead wires 1321a, 1322a located inside the shield member 15. In summary, the shield member 15 and the shield part mold 162 are sequentially arranged radially outward around the high-voltage lead wires 1321a, 1322a.

Accordingly, the shield member 15 may be arranged such that the exterior thereof is surrounded by the shield part mold 162. For this purpose, the shield member 15 is disposed inside a manufacturing mold of the mold transformer 1 before mold injection. That is, in order to add the shield member 15 to the existing mold transformer 1, only a simple process is required in which the high-voltage lead wires 1321a, 1322a are penetrated and coupled to the shield member 15 before mold injection.

Accordingly, the shield member 15 may be added without excessive change to the existing structure of the mold transformer 1. Accordingly, the mold transformer 1 is provided with the shield member 15, and may be manufactured in a simple and easy manner at the same time.

The shield part mold 162 is formed in a shape corresponding to the outer peripheral surface of the shield member 15. It will be understood that the shield member 15 is formed to have a height smaller than the height of the winding part 13, and thus, the shield part mold 162 is also formed to have a height smaller than the winding part mold 161.

The shield part mold 162 extends along the axial direction of the shield member 15. In an exemplary embodiment, the shield part mold 162 may extend with an increased axial cross-sectional area toward a boundary with the winding part mold 161 or a boundary with the bushing mold 163, which will be described below. This is to alleviate the electric field concentrated at an edge formed at the boundary.

In this case, the axial length of the shield part mold 162 is formed to be smaller than the axial length of the shield member 15. In other words, the distance between one end of the shield part mold 162 opposite to the iron core 12 and the iron core 12 is formed to be smaller than the distance between one end of the shield member 15 opposite to the iron core 12 and the iron core 12.

In the illustrated exemplary embodiment, the rear end of the shield part mold 162 is located ahead of the rear end of the shield member 15. In this case, the distance (d) between the rear end of the shield part mold 162 and the large diameter part 152 located at the rear end of the shield member 15 may be adjusted according to conditions such as the capacity of the mold transformer 1.

A semiconducting layer is coated on the surface of the shield part mold 162. In an exemplary embodiment, the surface of the shield part mold 162 may be coated with a semiconducting layer made of the same material as the semiconducting layer coated on the surface of the winding part mold 161.

A bushing mold 163 is located on one side of the shield part mold 162.

The bushing mold 163 insulates other portions of the high-voltage lead wires 1321a, 1322a located outside the shield member 15.

The bushing mold 163 is coupled to the winding part mold 161 with the shield part mold 162 interposed therebetween. In the illustrated exemplary embodiment, the winding part mold 161, the shield part mold 162 and the bushing mold 163 are arranged side by side in the front-to-back direction.

The bushing mold 163 is arranged to cover and surround another portion of the high-voltage lead wires 1321a, 1322a located outside the shield member 15. As described above, the high-voltage lead wires 1321a, 1322a extend in a direction away from the iron core 12. Accordingly, it will be understood that the bushing mold 163 also extends in a direction away from the iron core 12.

One end of the bushing mold 163 facing the iron core 12 contacts one end of the shield part mold 162 opposite to the iron core 12. Accordingly, the distance between one end of the bushing mold 163 facing the iron core 12 and the iron core 12 is also formed to be smaller than the distance between one end of the shield member 15 opposite to the iron core 12 and the iron core 12. In summary, the large diameter part 152 located at one end opposite to the iron core 12 of the shield member 15 is located inside the bushing mold 163.

Additionally, the height of the bushing mold 163 is formed to be greater than the height of the shield part mold 162. This is to exclude protrusion of the shield part mold 162 coated with the semiconducting layer. Accordingly, the electric field at the triple point where the shield part mold 162, the bushing mold 163 and the air meet may be alleviated.

There is a possibility that an electric field concentration phenomenon still exists at the boundary between the bushing mold 163 and the shield part mold 162 coated with a semiconducting layer. However, as described above, since part of the surface electric field of the mold part 16 is concentrated inside the mold part 16 by the shield member 15, the electric field generated at the boundary between the bushing mold 163 and the shield part mold 162 may be alleviated.

In the illustrated exemplary embodiment, the bushing mold 163 includes a protrusion part 1631 and a recessed part 1632.

The protrusion part 1631 is formed to extend radially outward from the high-voltage lead wires 1321a, 1322a. A plurality of protrusion parts 1631 may be provided. The recessed part 1632 is formed between two neighboring protrusion parts 1631. The recessed part 1632 is formed by being recessed radially inward of the high-voltage lead wires 1321a, 1322a. In summary, the protrusion part 1631 and recessed part 1632 are alternately arranged along the axial direction of the bushing mold 163.

As the bushing mold 163 includes a plurality of protrusion parts 1631 and recessed parts 1632, the contact area between the bushing mold 163 and the air may be further increased. Accordingly, the insulation distance of the bushing mold 163 may be further increased. As a result, the insulation performance of the mold transformer 1 may be further improved.

However, the structure of the mold part 16 is not limited to the illustrated shape and may be formed in various exemplary embodiments. For example, the mold part 16 may be integrally formed of an epoxy material.

Although the present disclosure has been described above with reference to preferred exemplary embodiments, the present disclosure is not limited to the configuration of the above-described exemplary embodiments.

In addition, the present disclosure can be modified and changed in various ways by those skilled in the art to which the present disclosure pertains without departing from the spirit and scope of the disclosure as set forth in the claims below.

Furthermore, the above exemplary embodiments may be configured by selectively combining all or part of each exemplary embodiment such that various modifications can be made.

### EXPLANATION OF REFERENCE NUMERALS

1: Mold transformer
11: Support part
111: Upper frame
112: Lower frame
113: Support
12: Iron core
13: Winding part
131: Low-voltage winding part
1311: First low-voltage winding
1312: Second low-voltage winding
132: High-voltage winding part
1321: First high-voltage winding
1321a: First high-voltage lead wire
1321b: First high-voltage terminal
1322: Second high-voltage winding
1322a: Second high-voltage lead wire
1322b: Second high-voltage terminal
14: Insulating member
15: Shield member
151: Small diameter part
152: Large diameter part
153: Ground part
16: Mold part
161: Winding part mold
162: Shield part mold
163: Bushing mold
1631: Protrusion part
1632: Recessed part

1. A mold transformer, comprising:
a winding part which is wound around an iron core, and has a lead wire that extends aways from the iron core;
a shield member which is formed in a columnar shape having a hollow space formed therein, and is formed of an electrically conductive material, wherein a part of the lead wire is inserted through and coupled to the hollow space; and
a mold part which is disposed to surround the winding part and the shield member, and is formed of an electrical insulation material.

2. The mold transformer of claim 1, wherein the mold part comprises:
a winding part mold which is disposed to cover and surround the winding part except for the lead wire;
a shield part mold which is coupled to one side of the winding part mold, and is disposed to cover and surround the shield member and a portion of the lead wire that is located inside the shield member; and
a bushing mold which is coupled to the winding part mold with the shield part mold interposed therebetween, and is disposed to cover and surround another portion of the lead wire that is located outside the shield member.

3. The mold transformer of claim 2, wherein the winding part mold and the shield part mold have a semiconducting layer coated on the surfaces thereof.

4. The mold transformer of claim 3, wherein the shield member comprises:
a small diameter part which is formed in a cylindrical shape; and
a large diameter part which is formed by extending from both ends of the small diameter part, and extends while being curved toward an outer peripheral surface of the small diameter part.

5. The mold transformer of claim 4, wherein the distance between one end of the shield member opposite to the iron core and the iron core is formed to be longer than the distance between one end of the shield part mold opposite to the iron core and the iron core.

6. The mold transformer of claim 4, wherein the large diameter part which is located at one end opposite to the iron core of the shield member extends and curves toward one end opposite to the iron core of the small diameter part.

7. The mold transformer of claim 6, wherein the large diameter part, which is located at one end opposite to the iron core of the shield member, has the end thereof in contact with a side surface of the small diameter part.

8. The mold transformer of claim 2, wherein the winding part comprises:
a low-voltage winding part which is wound on a portion of the iron core; and
a high-voltage winding part which is wound on another portion of the iron core, and is spaced apart from the low-voltage winding part.

9. The mold transformer of claim 8, wherein the low-volage winding part is respectively disposed on the upper and lower sides of the high-voltage winding part in the axial direction of the high-voltage winding part.

10. The mold transformer of claim 2, wherein the shield part mold is formed in a shape corresponding to the shield member.

11. The mold transformer of claim 10, wherein the shield part mold is extended with an axial cross-sectional area increasing toward a boundary with the winding part mold or a boundary with the bushing mold.

12. The mold transformer of claim 2, wherein the bushing mold comprises:
a plurality of protrusion parts which extend radially outwardly from the lead wire; and
a recessed part which is formed to be recessed between two adjacent protrusion parts,
wherein the protrusion part and the recessed part are arranged alternately along the axial direction.

13. The mold transformer of claim 2, wherein the mold part is made of an epoxy resin.

14. The mold transformer of claim 1, wherein the shield member comprises a ground part which is exposed to the outside of the mold part.

15. The mold transformer of claim 1, wherein the shield member is formed in a mesh structure.

16. The mold transformer of claim 1, wherein the shield member is formed of an aluminum (Al) material.
